(19) United States
(12) Patent Application Publication
(10) Pub. No.: US 2026/0221189 A1
(43) Pub. Date: Jul. 30, 2026

(54) NONVOLATILE MEMORY SYSTEM AND OPERATING METHOD THEREOF

(71) Applicant: SK hynix Inc., Gyeonggi-do (KR)

(72) Inventors: Paing Z. Htet, San Jose, CA (US); Geoff W. Bennett, San Jose, CA (US); Sebastian Uribe, San Jose, CA (US)

(21) Appl. No.: 19/036,524

(22) Filed: Jan. 24, 2025

(51) Int. Cl. G11C 16/10; G11C 16/04

(52) U.S. Cl. CPC G11C 16/10; G11C 16/0483

(57) ABSTRACT

A memory device includes a group of nonvolatile memory cells each configured to store therein multiple bits, which comprises higher and lower significant bits, the group comprising first and second parts. A control circuit caches the higher significant bits, and controls the memory device to perform a sequence of foggy and fine program operations on the group.

### BACKGROUND

### 1. Field

Embodiments of the present disclosure relate to a memory system and an operating method thereof.

### 2. Description of the Related Art

A memory system stores data in response to a request from a host system such as a computer, smartphone, or smart pad. An example of a memory system is a system configured to store data in a semiconductor memory, especially in a nonvolatile memory, such as a solid-state drive (SSD) or a memory card.

A memory system includes a memory device configured to store data and a controller configured to control the memory device. Generally, a memory device may be volatile or nonvolatile. Examples of a nonvolatile memory device are Read Only Memory (ROM), Programmable ROM (PROM), Electrically Programmable ROM (EPROM), Electrically Erasable and Programmable ROM (EEPROM), flash memory, Phase-change RAM (PRAM), Magnetic RAM (MRAM), Resistive RAM (RRAM), and Ferroelectric RAM (FRAM).

### SUMMARY

In an embodiment of the present disclosure, a memory system may include a memory device, a cache and a control circuit. The memory device may include a group of nonvolatile memory cells each configured to store therein multiple bits, which comprises higher and lower significant bits. The group may comprise first and second parts. The control circuit may cache the higher significant bits into the cache. The control circuit may control the memory device to perform a sequence of foggy and fine program operations on the group. The foggy program operation may be an operation of programming the first part with the higher significant bits to become in a non-readable state and programming the second part with the lower significant bits to become in a readable state. The fine program operation may be an operation of programming the group with the multiple bits, which are combination of the higher significant bits from the cache and the lower significant bits from the second part.

The cache may include one or more nonvolatile single level cells (SLCs).

The multiple bits may be four bits.

The fine program operation may be the operation of programming the group with the multiple bits to have threshold voltages corresponding to sixteen erase and program states.

The higher significant bits may be two bits of most significant bit (MSB) and upper-central significant bit (UCSB). The lower significant bits may be two bits of least significant bit (LSB) and lower-central significant bit (LCSB).

The first part may include the memory cells for MSB and UCSB pages. The second part may include the memory cells for LSB and LCSB pages.

The foggy program operation may be the operation of programming to have threshold voltages corresponding to 7 states with 3 valleys each having a high margin for internal read of 2 pages of data.

The foggy program operation may be the operation of programming to have threshold voltages corresponding to 8 states with 3 valleys each having a high margin for internal read of 2 pages of data.

The foggy program operation may be the operation of programming to have threshold voltages corresponding to 10 states with 3 valleys each having a median margin for internal read of 2 pages of data.

The foggy program operation may be the operation of programming to have threshold voltages corresponding to 11 states with 5 valleys each having a low margin for internal read of 2 pages of data.

The foggy program operation may be the operation of programming to have threshold voltages corresponding to 13 states with 3 valleys each having a low margin for internal read of 2 pages of data.

In another embodiment of the present disclosure, an operating method of a memory system may include caching higher significant bits into a cache and performing, with multiple bits comprising the higher and lower significant bits, a sequence of foggy and fine program operations on a group of nonvolatile memory cells comprising first and second parts. The foggy program operation may be an operation of programming the first part with the higher significant bits to become in a non-readable state and programming the second part with the lower significant bits to become in a readable state. The fine program operation may be an operation of programming the group with the multiple bits, which are combination of the higher significant bits from the cache and the lower significant bits from the second part.

The multiple bits may be four bits.

The fine program operation may be the operation of programming the group with the multiple bits to have threshold voltages corresponding to sixteen erase and program states.

The higher significant bits may be two bits of most significant bit (MSB) and upper-central significant bit (UCSB). The lower significant bits may be two bits of least significant bit (LSB) and lower-central significant bit (LCSB).

The foggy program operation may be the operation of programming to have threshold voltages corresponding to 7 states with 3 valleys each having a high margin for internal read of 2 pages of data.

The foggy program operation may be the operation of programming to have threshold voltages corresponding to 8 states with 3 valleys each having a high margin for internal read of 2 pages of data.

The foggy program operation may be the operation of programming to have threshold voltages corresponding to 10 states with 3 valleys each having a median margin for internal read of 2 pages of data.

The foggy program operation may be the operation of programming to have threshold voltages corresponding to 11 states with 5 valleys each having a low margin for internal read of 2 pages of data.

The foggy program operation may be the operation of programming to have threshold voltages corresponding to 13 states with 3 valleys each having a low margin for internal read of 2 pages of data.

Additional embodiments of the present disclosure will become apparent from the following description.

### BRIEF DESCRIPTION OF THE DRAWINGS

FIG. 1 illustrates a memory system.

FIG. 2 illustrates a data processing system.

FIG. 3 illustrates a controller.

FIG. 4 illustrates a memory device.

FIGS. 5 and 6 illustrate the partial-foggy-fine program scheme on TLCs.

FIGS. 7 to 9 illustrate read operations on LSB, CSB and MSB pages of TLCs.

FIG. 10 illustrates voltages applied to a word line and bit lines during a program operation on TLCs.

FIG. 11 schematically illustrates pages included in a memory block.

FIGS. 12 and 13 schematically illustrate a one-shot program scheme on TLCs.

FIGS. 14 and 15 schematically illustrate a one-shot program scheme on QLCs.

FIG. 16 schematically illustrates a hybrid-foggy-fine program scheme on QLCs.

FIGS. 17 to 21 schematically illustrate various embodiments of a hybrid-foggy-fine program scheme on QLCs.

### DETAILED DESCRIPTION

Various embodiments of the present disclosure are described below in more detail with reference to the accompanying drawings. The present invention may, however, be embodied in different forms and thus should not be construed as limited to the embodiments set forth herein. Rather, these embodiments are provided so that this disclosure conveys the scope of the present invention to those skilled in the art. Moreover, reference herein to “an embodiment,” “another embodiment,” or the like is not necessarily to only one embodiment, and different references to any such phrase are not necessarily to the same embodiment(s). The term “embodiments” as used herein does not necessarily refer to all embodiments. Throughout this disclosure, like reference numerals refer to like parts in the figures and embodiments of the present disclosure.

Embodiments of the present disclosure may be implemented in numerous ways, including as a process; an apparatus; a system; a computer program product embodied on a computer-readable storage medium; and/or a processor, such as a processor suitable for executing instructions stored on and/or provided by a memory coupled to the processor. In this specification, these embodiments, or any other form that the present invention may take, may be referred to as techniques. In general, the order of the operations of disclosed processes may be altered within the scope of the present invention. Unless stated otherwise, a component such as a processor or a memory described as being suitable for performing a task may be implemented as a general device or circuit component that is configured or otherwise programmed to perform the task at a given time or as a specific device or circuit component that is manufactured to perform the task. As used herein, the term ‘processor’ or the like refers to one or more devices, circuits, and/or processing cores suitable for processing data, such as computer program instructions.

The methods, processes, and/or operations described herein may be performed by code or instructions to be executed by a computer, processor, controller, or other signal processing device. The computer, processor, controller, or other signal processing device may be those described herein or one in addition to the elements described herein. Because the algorithms that form the basis of the methods (or operations of the computer, processor, controller, or other signal processing device) are described herein, the code or instructions for implementing the operations of the method embodiments may transform the computer, processor, controller, or other signal processing device into a special-purpose processor for performing methods herein.

As used in this disclosure, the term “circuitry” or “logic” refers to all of the following: hardware-only circuit implementations (such as implementations in only analog and/or digital circuitry); combinations of circuits and software (and/or firmware) such as (as applicable) to a combination of processor(s) or to portions of processor(s)/software (including digital signal processor(s)), software and memory(ies) that work together to cause an apparatus such as a mobile phone or server, to perform various functions; and circuits such as a microprocessor(s) or a portion of a microprocessor(s) that require software or firmware for operation even if the software or firmware is not physically present. This definition of “circuitry” or “logic” applies to all uses of this term in this application, including in any claims. As a further example, as used in this application, the term “circuitry” or “logic” also covers an implementation of merely a processor (or multiple processors) or portion of a processor and its (or their) accompanying software and/or firmware. The term “circuitry” or “logic” also covers, for example, and if applicable to a particular claim element, an integrated circuit for a memory device.

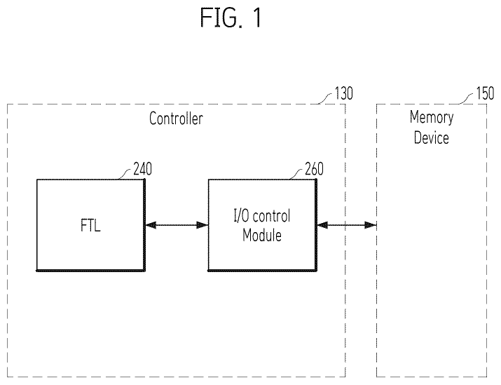

FIG. 1 illustrates a memory system.

Referring to FIG. 1, the memory system may include a memory device 150 and a controller 130. The memory device 150 and the controller 130 may be physically or functionally separated from each other. The memory device 150 and the controller 130 may communicate with each other.

The controller 130 may include a flash translation layer (FTL) 240 and an input/output (I/O) control module 260. The FTL 240 may perform a data processing operation for transferring host data from a host 102 to the memory device 150 in order to store the host data in the memory device 150. Because a logical address scheme identified by the host 102 and a physical address scheme identified within the memory system are different from each other, the FTL 240 may determine a location, in which the data is to be stored in the memory device 150. The FTL 240 may generate map data for associating a logical address with a physical address of the data. The logical address of the data may be determined and identified by the host 102 and the physical address of the data may be determined and identified by the memory system.

The I/O control module 260 may control the operation of storing, in the memory device 150, the data transferred from the FTL 240. The memory device 150 may include a plurality of planes, each including a plurality of nonvolatile memory cells. When the I/O control module 260 transmits a read command to the memory device 150, data may be read from the memory cells and output to the I/O control module 260.

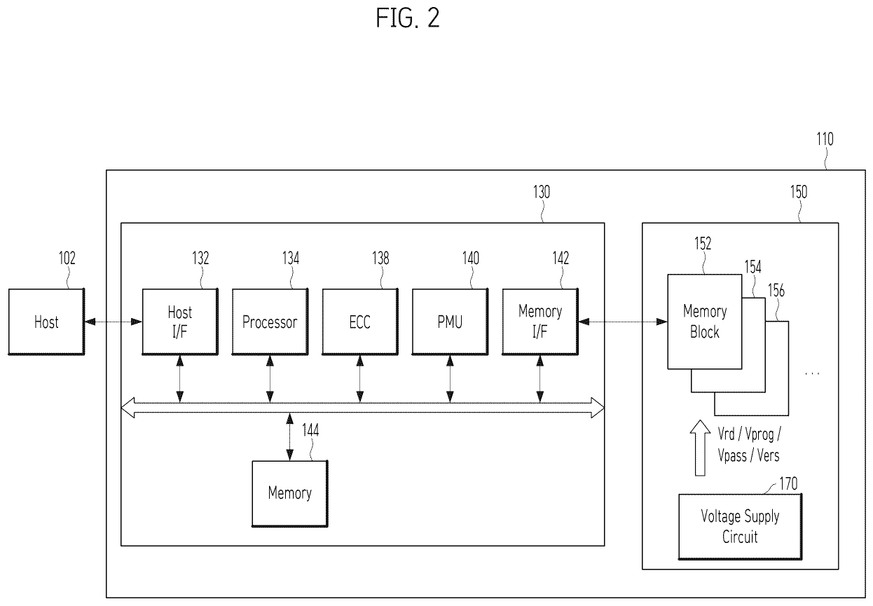

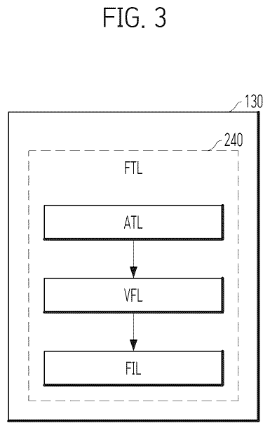

According to an embodiment, the I/O control module 260 may be included in a memory interface 142 shown in FIGS. 2 and 3. According to an embodiment, the I/O control module 260 may be arranged between the FTL 240 and the memory interface 142 shown in FIGS. 2 and 3.

The memory plane may include at least one memory block, a driving circuit configured to control an array including the nonvolatile memory cells, and at least one buffer configured to temporarily store data input to or output from the plurality of nonvolatile memory cells. The memory plane may be understood as a logical or physical partition.

The memory device 150 may include a plurality of memory blocks. A memory block may be understood as a group of nonvolatile memory cells, from which data is erased together through an erase operation. Each of the memory blocks may include a page as a group of nonvolatile memory cells, which store data together during a program operation and output data together during a read operation.

The memory system may perform a two-step program operation or a multi-step program operation to program multi-bit data. In an embodiment, the memory system may perform a foggy program operation and a fine program operation to program the multi-bit data.

The memory system may perform a one-shot program operation to program multi-bit data. The one-shot program operation may be performed through plural program operations in which plural ISPP step pulses are applied successively to program multi-bit data in a nonvolatile memory cell until the nonvolatile memory cell connected to a specific word line is fully programmed with the multi-bit data. In the one-shot program operation, plural program pulses are alternatively applied to plural word lines to perform plural program operations regarding the multi-bit data. While a program operation is performed through a specific word line, another program operation may not be performed through another word line.

FIG. 2 illustrates a data processing system.

Referring to FIG. 2, the data processing system 100 may include the host 102 coupled with the memory system 110. The memory device 150 and the controller 130 may be implemented with a single chip or a plurality of chips.

The memory device 150 may include a voltage supply circuit 170 configured to supply voltages for operations on the memory block. The memory device 150 may store information regarding various voltages to be supplied to the memory block depending on an operation. For example, when multi-bit data are stored in a nonvolatile memory cell in the memory block, plural levels of the read voltage Vrd may be required for reading the multi-bit data.

The host 102 may include a portable electronic device, e.g., a mobile phone, an MP3 player, a laptop computer, etc., or a non-portable electronic device, e.g., a desktop computer, a game player, a television, a projector, etc.

The controller 130 may control the memory device 150 in response to a request from the host 102. For example, the controller 130 may perform a read operation to provide the host 102 with data read from the memory device 150 and may perform a write or program operation to store, in the memory device 150, data provided from the host 102. In order to perform data I/O operations, the controller 130 may control and manage internal operations of reading data, programming data, erasing data, or the like.

Referring to FIG. 2, the controller 130 may include a host interface 132, a processor 134, an error correction code (ECC) circuitry 138, a power management unit (PMU) 140, a memory interface 142, and a memory 144.

For example, the memory system 110 may be implemented with any of various types according to a protocol of a host interface. Non-limiting examples of suitable memory system 110 may include a solid state drive (SSD), a multimedia card (MMC), an embedded MMC (eMMC), a reduced size MMC (RS-MMC), a micro-MMC, a secure digital (SD) card, a mini-SD, a micro-SD, a universal serial bus (USB) memory device, a universal flash storage (UFS) device, a compact flash (CF) card, a smart media (SM) card, a memory stick, and the like.

The host interface 132 may be suitable for transmitting a signal to and receiving a signal from the host 102. The host 102 and the memory system 110 may communicate with each other according to a predetermined communication protocol. Examples of the protocol may include Universal Serial Bus (USB), Multi-Media Card (MMC), Parallel Advanced Technology Attachment (PATA), Small Computer System Interface (SCSI), Enhanced Small Disk Interface (ESDI), Integrated Drive Electronics (IDE), Peripheral Component Interconnect Express (PCIe or PCI-e), Serial-attached SCSI (SAS), Serial Advanced Technology Attachment (SATA), Mobile Industry Processor Interface (MIPI), and the like. The host interface 132 may be implemented as a type of layer such as a host interface layer (HIL).

Referring to FIG. 2, the ECC circuitry 138 may correct error bits of data read from the memory device 150 and may include an encoder and a decoder. The encoder may perform an encoding operation on data to be programmed in the memory device 150 to generate encoded data into which a parity bit is added. The decoder may detect and correct error bits in the encoded data read from the memory device 150. For example, after performing a decoding operation on the data read from the memory device 150, the ECC circuitry 138 may determine whether the error correction decoding has succeeded or not, and outputs a success signal or a fail signal based on a result of the decoding operation. In order to correct the error bits of the encoded data generated during the ECC encoding process, the ECC circuitry 138 may use the parity bit included in the encoded data. When a number of error bits is a threshold or greater, the ECC circuitry 138 may not correct the error bits and instead may output the fail signal.

According to an embodiment, the ECC circuitry 138 may be suitable for an error correction operation based on a coded modulation such as a low density parity check (LDPC) code, a Bose-Chaudhuri-Hocquenghem (BCH) code, a turbo code, a Reed-Solomon (RS) code, a convolution code, a recursive systematic code (RSC), a trellis-coded modulation (TCM), a Block coded modulation (BCM), or the like.

The PMU 140 may control electrical power provided to the controller 130. The PMU 140 may generate a trigger signal to enable the memory system 110 to urgently back up a current state when the electrical power supplied to the memory system 110 is unstable. According to an embodiment, the PMU 140 may be suitable for saving electrical power for an emergency.

The memory interface 142 may serve as an interface for communication between the controller 130 and the memory device 150 for the controller 130 to control the memory device 150. The memory interface 142 may generate a control signal for the memory device 150 and may process data input to, or output from, the memory device 150 under the control of the processor 134.

For example, when the memory device 150 includes a NAND flash memory, the memory interface 142 may include a NAND flash controller (NFC). The memory interface 142 may be implemented as a type of layer such as a flash interface layer (FIL).

The memory 144 may serve as a working memory of the memory system 110 110 or the controller 130 by temporarily storing transactional data for operations performed in the memory system 110 and the controller 130. For example, the memory 144 may temporarily store data read from the memory device 150 before the read data is output to the host 102. In addition, the controller 130 may temporarily store, in the memory 144, write data provided from the host 102 before programming the write data in the memory device 150. When the controller 130 controls operations of the memory device 150, data transferred between the controller 130 and the memory device 150 may be temporarily stored in the memory 144.

The memory 144 may include one or more of a command queue, a program memory, a data memory, a write buffer/cache, a read buffer/cache, a data buffer/cache, a map buffer/cache, and so on. The controller 130 may allocate spaces in the memory 144 for a data I/O operation. For example, the write buffer established in the memory 144 may temporarily store write data as a target of a program operation.

The memory 144 may be implemented with a volatile memory. For example, the memory 144 may be implemented with a static random access memory (SRAM), a dynamic random access memory (DRAM), or both. Although FIG. 2 illustrates the memory 144 disposed within the controller 130, the memory 144 may be provided within or external to the controller 130. For instance, the memory 144 may be embodied by an external volatile memory having a memory interface transferring data and/or signals between the memory 144 and the controller 130.

The processor 134 may control the overall operations of the memory system 110. For example, the processor 134 may control a program operation or a read operation of the memory device 150. The processor 134 may execute firmware to control the program operation or the read operation in the memory system 110. Herein, the firmware may be the FTL 240. The processor 134 may be implemented with a microprocessor, a central processing unit (CPU), or the like.

The processor 134 may perform an operation in response to or without a request from the host 102. The controller 130 may perform foreground and background operations of reading, writing and erasing data in the memory device 150. The background operation may include garbage collection, wear leveling, bad block management (identifying and processing bad blocks), or the like.

Referring to FIG. 2, the memory device 150 may include a plurality of memory blocks 152 to 156. Each memory block may have a three-dimensional stack structure for a high integration. The plurality of memory blocks 152, 154, and 156 may be any of single-level cell (SLC) memory blocks, multi-level cell (MLC) memory blocks, or the like, according to the number of bits that may be stored in one memory cell.

In an embodiment, the memory device 150 may be implemented with MLC memory blocks such as a double-level cell (DLC) memory block, a triple-level cell (TLC) memory block, a quadruple-level cell (QLC) memory block, and a combination thereof. The DLC memory block may include a plurality of pages implemented by memory cells, each memory cell suitable for storing 2-bit data. The TLC memory block may include a plurality of pages implemented by memory cells, each memory cell suitable for storing 3-bit data. The QLC memory block may include a plurality of pages implemented by memory cells, each memory cell suitable for storing 4-bit data. In another embodiment, the memory device 150 may be implemented with a block including a plurality of pages implemented by memory cells, each memory cell suitable for storing five or more bits of data.

The memory device 150 may be embodied as a nonvolatile memory such as a flash memory, for example, a NAND flash memory, a NOR flash memory, or the like. The memory device 150 may be implemented by at least one of a phase change random access memory (PCRAM), a ferroelectrics random access memory (FRAM), a transfer torque random access memory (STT-RAM), and a spin transfer torque magnetic random access memory (STT-MRAM), or the like.

FIG. 3 illustrates the controller 130.

Referring to FIG. 3, the FTL 240 in the controller 130 may be divided into three layers: an address translation layer ATL, a virtual flash layer VFL and a flash Interface Layer FIL.

For example, the address translation layer ATL may convert a logical address LA transmitted from a file system into a logical page address. The address translation layer ATL may perform an address translation process regarding a logical address space. That is, the address translation layer ATL may perform an address translation process based on mapping information in which the logical page address LPA of the flash memory 140 is mapped to the logical address LA transmitted from the host. Such logical-to-logical address mapping information (hereinafter referred to as L2L mapping) may be stored in an area in which metadata is stored in the memory device 150.

The virtual flash layer VFL may convert the logical page address LPA, which is mapped by the address translation layer ATL, into a virtual page address VPA. Here, the virtual page address VPA may correspond to a physical address of a virtual memory device. That is, the virtual page address VPA may correspond to the memory block 60 in the memory device 150. If there is a bad block among the memory blocks 60 in the memory device 150, the bad block may be excluded by the virtual flash layer VFL. In addition, the virtual flash layer VFL may include a recovery algorithm for restoring the logical-to-virtual address mapping information (L2V mapping) stored in the memory device 150 and mapping information in the data region for storing user data. The recovery algorithm may be suitable for recovering the logical-to-virtual address mapping information (L2V mapping). The virtual flash layer VFL may perform an address conversion process regarding the virtual address space, based on the logical-to-virtual address mapping information (L2V mapping) restored through the recovery algorithm.

The flash interface layer FIL may convert a virtual page address of the virtual flash layer VFL into a physical page address of the memory device 150. The flash interface layer FIL performs a low-level operation for interfacing with the memory device 150. For example, the flash interface layer FIL may include a low-level driver for controlling hardware of the memory device 150, an error correction code (ECC) for checking and correcting an error in data transmitted from the memory device 150, and a module for performing operations such as a bad block management.

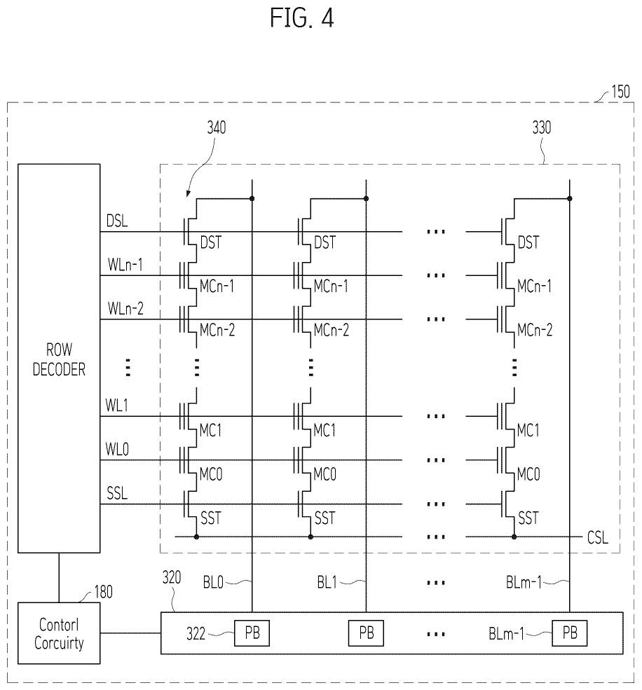

FIG. 4 illustrates the memory device 150.

Referring to FIG. 4, the memory device 150 may include at least one memory group 330 having a plurality of cell strings 340. Each cell string 340 may include a plurality of nonvolatile memory cells MC0 to MCn-1 connected to a respective bit line of a plurality of bit lines BL0 to BLm-1. The cell strings 340 may be disposed in respective columns of the memory group 330 and each cell string 340 may include at least one drain select transistor DST and at least one source select transistor SST. The nonvolatile memory cells MC0 to MCn-1 of each cell string 340 may be connected in series between a drain select transistor DST and a source select transistor SST. Each of the nonvolatile memory cells MC0 to MCn-1 may be configured as a multi-level cell (MLC) that stores data having plural bits per cell. The cell strings 340 may be electrically connected to the corresponding bit lines of the bit lines BL0 to BLm-1.

The memory group 330 may include NAND-type flash memory cells MC0 to MCn-1. In another embodiment, the memory group 330 may be implemented as a NOR-type flash memory, a hybrid flash memory in which at least two different types of memory cells are mixed or combined, or a one-chip NAND flash memory in which a controller is embedded in a single memory chip. In an embodiment, the memory group 330 may include a flash memory cell including a charge trap flash (CTF) layer that includes a conductive floating gate or insulating layer.

The memory group 330 in memory device 150 may include one or more memory blocks. According to an embodiment, the memory device 150 may have a two-dimensional (2D) or three-dimensional (3D) structure. For example, each of the memory blocks in the memory device 150 may be implemented as a 3D structure or a vertical structure. Each of the memory blocks may have a three-dimensional structure extending along first to third directions, for example, an x-axis direction, a y-axis direction, and a z-axis direction.

The memory group 330 including the plurality of memory blocks may be coupled to a plurality of bit lines BL, a plurality of string select lines SSL, and a plurality of drain select lines DSL, a plurality of word lines WL, a plurality of dummy word lines DWL, and a plurality of common source lines CSL. The memory group 330 may include a plurality of NAND strings NS corresponding to the respective cell strings 340. Each NAND string NS may include a plurality of memory cells MC and may be connected to a respective bit line of the bit lines BL. In addition, the string select transistor SST of each NAND string NS may be connected to a common source line CSL, and the drain select transistor DST of each NAND string NS may be connected to a corresponding bit line BL. In each NAND string NS, the memory cells MC may be arranged between the string select transistor SST and the drain select transistor DST.

The memory device 150 may include the voltage supply circuit 170 which may supply a word line voltage e.g., one or more predetermined voltages such as a program voltage, a read voltage, and a pass voltage, for respective word lines according to an operation mode, or may supply a voltage to a bulk (e.g., a well region) in which each memory block including the memory cells MC are formed. In this case, a voltage generating operation of the voltage supply circuit 170 may be performed under the control circuitry 180. Also, the voltage supply circuit 170 may generate a plurality of variable read voltages to distinguish a plurality of data from each other. The plurality of variable read voltages may be applied to nonvolatile memory cells in the memory group 330.

In response to the control of the control circuitry 180, one of the memory blocks (or sectors) of the memory cell array may be selected, and one of the word lines of the selected memory block may be selected. Word line voltages may be supplied to the selected word line and the unselected word line, individually. The voltage supply circuit 170 may include a voltage generation circuit for generating target voltages having various levels.

In an embodiment, the voltage supply circuit 170 may be coupled to a first pin or pad receiving a first power voltage VCC applied from the outside (e.g., an external device) and a second pin or pad receiving the second power voltage VPP applied from the external device. The second power voltage VPP may have a greater voltage level, e.g., twice or higher than that of the first power voltage VCC. For example, the first power voltage VCC may have a voltage level of 2.0V to 5.5V, while the second power supply voltage may have a voltage level of 9V to 13V.

The voltage supply circuit 170 may include a voltage generation circuit for more rapidly generating the target voltages of various levels used in the memory group 330. The voltage generation circuit may use the second power supply voltage VPP to generate a target voltage, which may have a higher voltage level than the second power voltage VPP.

The memory device 150 may include a read/write circuit 320 controlled by the control circuitry 180. The read/write circuit 320 may operate as a sense amplifier or a write driver according to an operation mode. For example, in a verify operation and a read operation, the read/write circuit 320 may operate as a sense amplifier for reading the data from the memory cell array. In a program operation, the read/write circuit 320 may operate as a write driver that controls potentials of bit lines according to data to be stored in the memory cell array. The read/write circuit 320 may receive the data to be programmed to the cell array from page buffers during the program operation. The read/write circuit 320 may drive bit lines based on the input data. To this end, the read/write circuit 320 may include a plurality of page buffers (PB) 322 to 326 each corresponding to each column (or each bit line) or each column pair (or each bit line pair). According to an embodiment, a plurality of latches may be included in each of the page buffers.

According to an embodiment, the memory device 150 may receive a write command, write data and a physical address indicating a location, in which the write data are to be stored. The control circuitry 180 causes the voltage supply circuit 170 to generate a program pulse, a pass voltage, etc., used for a program operation performed in response to a write command, and to generate one or more voltages used for a verification operation performed after the program operation.

When a multi-bit data is programmed in the nonvolatile memory cells of the memory group 330, the error rate may be higher than that when a single-bit data is stored in the nonvolatile memory cells. For example, an error in the nonvolatile memory cells may be induced due to cell-to-cell interference (CCI). In order to reduce error in the nonvolatile memory cells, a width (deviation) of a threshold voltage distribution corresponding to stored data between the nonvolatile memory cells, should be reduced.

To this end, the memory device 150 may perform an incremental step pulse programming (ISPP) operation to effectively make a narrow threshold voltage distribution of the nonvolatile memory cells. In an embodiment, the memory device 150 may use the ISPP operation for multi-step program operations.

By a foggy program operation disclosed below, formed are threshold voltage distribution corresponding to a part of all states supposed to be formed. In this disclosure, a partial-foggy program operation may be the foggy program operation to form the threshold voltage distribution corresponding to a part of all states supposed to be formed. In this disclosure, a partial-foggy-fine program scheme may include the partial-foggy program operation and a fine program operation. As an example, a partial-foggy-fine program operation on TLCs is described below. However, the partial-foggy-fine program operation may be applied to memory cells of various multiple bits per cell (BPC) such as QLCs.

The partial-foggy-fine program scheme may improve an interference phenomenon affecting an adjacent cell due to a program operation in a three-dimensional memory cell array. The partial-foggy-fine program scheme may refer to a program scheme which includes a foggy programming step of programming selected memory cells to an intermediate program state P_{IS} first, and then a fine programming step of programming the selected memory cells to target program states PV1 to PV7.

The partial-foggy-fine program scheme may include step S100 of performing a partial-foggy program operation on selected memory cells using an intermediate verify voltage VRF_{IS} and step S200 of performing a fine program operation on the selected memory cells using first to seventh verify voltages. The selected memory cells may belong to a physical page subject to the program operation. The selected memory cells may be coupled to a selected word line.

At step S100, threshold voltages of the selected memory cells may change from an erase state E₀ to an erase state E_{IS} and the intermediate program state P_{IS}. The partial-foggy program operation may temporarily change the threshold voltages of the selected memory cells to the erase state E_{IS} and the intermediate program state P_{IS} before changing, through the fine program operation, the threshold voltages of the selected memory cells to an erase state E and the target program states PV1 to PV7. The intermediate verify voltage VRF_{IS} may verify the threshold voltages of the selected memory cells, which have moved from the erase state E₀ to the intermediate program state P_{IS}.

At step S200, the threshold voltages of the selected memory cells may change from the erase state E_{IS} and the intermediate program state P_{IS} to the erase state E and the target program states PV1 to PV7. Since the selected memory cells are TLCs, the threshold voltages of the memory cells may belong to one of the eight states, i.e., the erase state E and the target program states PV1 to PV7 after completion of the partial-foggy-fine program operation. When each memory cell stores N bits, threshold voltages of the memory cells may belong to one of 2^{N} states, i.e., the erase state E and target program states PV1 to PV(2^{N}-1) after completion of a program operation.

For example, at step S200, the threshold voltages of the selected memory cells of the erase state E_{IS} may be changed to the erase state E and the first to third target program states PV1 to PV3. When each of the selected memory cells stores N bits, the threshold voltages of the selected memory cells of the erase state E_{IS} may be changed to the erase state E and the first to (2^{N-1}-1)th target program states PV1 to PV(2^{N-1}-1).

In addition, at step S200, the threshold voltages of the selected memory cells of the intermediate program state P_{IS} may be changed to the fourth to seventh target program states PV4 to PV7. When each of the selected memory cell stores N bits, the threshold voltages of the selected memory cells of the intermediate program state P_{IS} may be changed to (2^{N-1})th to(2^{N-1})th target program states.

The first to seventh verify voltages may verify the threshold voltages of the selected memory cells, which have moved from the erase state E_{IS} and the intermediate program state P_{IS} to the erase state E and the target program states PV1 to PV7. For example, when each of the selected memory cell stores N bits, first to (2^{N-1})th verify voltages may verify the threshold voltages of the selected memory cells.

Step S100 of performing the partial-foggy program operation on the selected memory cells using the intermediate verify voltage VRF_{IS} may include step S310 of applying a program inhibition voltage to bit lines coupled to the selected memory cells programmed to have the threshold voltages corresponding to the intermediate program state P_{IS} and the erase state E_{IS}; step S330 of applying a program permission voltage to bit lines coupled to the selected memory cells not yet programmed to have the threshold voltages corresponding to the intermediate program state P_{IS}; step S350 of applying a program voltage to a word line coupled to the selected memory cells; step S370 of performing a verify operation on the selected memory cells using the intermediate verify voltage VRF_{IS}; and step S390 of determining whether the selected memory cells are completely programmed to the intermediate program state P_{IS}.

Each of the selected memory cells of the erase state E_{IS} may have a least significant bit (LSB) of 1. The selected memory cells to be programmed to the intermediate program state P_{IS} may have a least significant bit (LSB) of 0. The partial-foggy program operation of step S100 may be substantially a SLC program operation.

Steps S310 to S370 may be repeated until the selected memory cells are programmed to have the threshold voltages corresponding to the intermediate program state. The partial-foggy program operation on the selected memory cells may include a plurality of program loops. Each of the program loops may include steps S310 to S370.

At step S310, as a result of performing a verify operation in the previous program loop at step S370, a program inhibition voltage may be applied to bit lines respectively coupled to the selected memory cells, which have been completely programmed to have the threshold voltages corresponding to the intermediate program state P_{IS} and the erase state E_{IS}. The threshold voltages of the program-completed memory cells of the intermediate program state P_{IS} and the erase state E_{IS} may be avoided from further programming. Thus, the program inhibition voltage may be applied to the bit lines respectively coupled to the program-completed memory cells so as not to increase the threshold voltages of the program-completed memory cells even when a program voltage is applied to a selected word line at step S350.

At step S330, a program permission voltage may be applied to bit lines coupled to the selected memory cells, which are not yet programmed to have the threshold voltages corresponding to the intermediate program state P_{IS} and the erase state E_{IS} as the result of performing the verify operation in the previous program loop at step S370. In this manner, when the program voltage is applied to the selected word line at step S350, the threshold voltages of the program-incomplete memory cells may increase.

At step S350, a program voltage may be applied to a word line coupled to the selected memory cells. The threshold voltages of program-incomplete memory cells may increase whereas the threshold voltages of the program-inhibited memory cells may not. The program-incomplete memory cells may be the selected memory cells still having the threshold voltages lower than the intermediate verify voltage VRF_{IS}. The program-inhibited memory cells may be the selected memory cells already having the threshold voltages greater than the intermediate verify voltage VRF_{IS}. At the early stage of the partial-foggy program operation, all memory cells may have threshold voltages corresponding to the erase state E₀. Therefore, all memory cells to be programmed to have the threshold voltages corresponding to the intermediate program state P_{IS} may be program-incomplete memory cells. As a program loop is repeated, the threshold voltages of the program-incomplete memory cells may gradually increase and the threshold voltages of some of the selected memory cells may become greater than the intermediate verify voltage VRF_{IS}. The selected memory cells, the threshold voltages of which become greater than the intermediate verify voltage VRF_{IS}, may become the program-inhibited cells. When the program loop continues to be repeated, the threshold voltages of the selected memory cells may eventually become greater than the intermediate verify voltage VRF_{IS}. As a result, all selected memory cells may be programmed to the intermediate program state P_{IS} and thus may be the program-inhibited cells.

The selected memory cells having the threshold voltages corresponding to the erase state E_{IS} may become the program-inhibited cells from the early stage of the partial-foggy program operation.

At step S370, a verify operation may be performed on the selected memory cells, through the intermediate verify voltage VRF_{IS}. The intermediate verify voltage VRF_{IS} may be applied to the selected word line. It may be determined whether the threshold voltages of the selected memory cells are greater than the intermediate verify voltage VRF_{IS}. The selected memory cells having threshold voltages greater than the intermediate verify voltage VRF_{IS} as a result of step S370 may become the program-inhibited cells.

Step S100 may end when the threshold voltages of all selected memory cells are determined as greater than the intermediate verify voltage VRF_{IS} at step S390. When the threshold voltages of at least some of the selected memory cells are determined as lower than the intermediate verify voltage VRF_{IS} at step S390, the process may proceed to step S310 and a subsequent program loop may be repeated.

As the partial-foggy program operation is performed as described above, a threshold voltage distribution corresponding to the initial erase state E₀ may be changed to the erase state E_{IS} and the intermediate program state P_{IS}. The memory cells of the erase state E_{IS} and the intermediate program state P_{IS} may be differentiated from each other according to the LSB of each memory cell. In other words, the partial-foggy program operation may be substantially the same as a SLC program operation based on the LSB of each of the memory cells. The threshold voltage distribution of the memory cells after the completion of the partial-foggy program operation may be divided into the erase state E_{IS} and the intermediate program state P_{IS}. Therefore, the LSB of each memory cell may be read using an intermediate read voltage R_{IS}.

Step S200 of performing the fine program operation on the selected memory cells using the first to seventh verify voltages may include step S315 of applying a program inhibition voltage to bit lines coupled to the selected memory cells programmed to have the threshold voltages corresponding to the target program states PV1 to PV7; step S335 of applying a program permission voltage to bit lines coupled to the selected memory cells not yet programmed to have the threshold voltages corresponding to the target program states PV1 to PV7; step S355 of applying a program voltage to a word line coupled to the selected memory cells; step S375 of performing a verify operation on the selected memory cells using first to seventh verify voltages VRF1 to VRF7; and step S395 of determining whether the selected memory cells are completely programmed to the target program states PV1 to PV7.

Steps S315 to S375 may be repeated until the selected memory cells are programmed to have the threshold voltages corresponding to the target program states. The fine program operation of the selected memory cells may include a plurality of program loops. Each of the program loops may include steps S315 to S375.

At step S315, as a result of performing a verify operation in the previous program loop at step S375, a program inhibition voltage may be applied to bit lines respectively coupled to the selected memory cells, which have been completely programmed to have the threshold voltages corresponding to the target program states PV1 to PV7 and the erase state E. The threshold voltages of the program-completed memory cells of the target program states PV1 to PV7 and the erase state E may be avoided from further programming. Thus, the program inhibition voltage may be applied to the bit lines respectively coupled to the program-completed memory cells so as not to increase the threshold voltages of the program-completed memory cells even when a program voltage is applied to a selected word line at step S355.

At step S335, a program permission voltage may be applied to bit lines coupled to the selected memory cells, which are not yet programmed to have the threshold voltages corresponding to the target program states PV1 to PV7 and the erase state E as the result of performing the verify operation in the previous program loop at step S375. In this manner, when the program voltage is applied to the selected word line at step S355, the threshold voltages of the program-incomplete memory cells may increase.

At step S355, a program voltage may be applied to a word line coupled to the selected memory cells. The threshold voltages of program-incomplete memory cells may increase whereas the threshold voltages of the program-inhibited memory cells may not. The program-incomplete memory cells may be the selected memory cells still having the threshold voltages lower than the corresponding first to seventh verify voltages VRF1 to VRF7. The program-inhibited memory cells may be the selected memory cells already having the threshold voltages greater than the corresponding first to seventh verify voltages VRF1 to VRF7. At the early stage of the fine program operation, all memory cells may have threshold voltages corresponding to the erase state E. Therefore, all memory cells to be programmed to have the threshold voltages corresponding to the respective target program states PV1 to PV7 may be program-incomplete memory cells. As a program loop is repeated, the threshold voltages of the program-incomplete memory cells may gradually increase and the threshold voltages of some of the selected memory cells may become greater than the corresponding first to seventh verify voltages VRF1 to VRF7. The selected memory cells, the threshold voltages of which become greater than the corresponding first to seventh verify voltages VRF1 to VRF7, may become the program-inhibited cells. When the program loop continues to be repeated, the threshold voltages of the selected memory cells may eventually become greater than the corresponding first to seventh verify voltages VRF1 to VRF7. As a result, all selected memory cells may be programmed to have the threshold voltages corresponding to the respective target program states PV1 to PV7 and thus may be the program-inhibited cells.

The selected memory cells having the threshold voltages corresponding to the erase state E may become the program-inhibited cells from the early stage of the partial-foggy program operation.

At step S375, a verify operation may be performed on the selected memory cells, through the corresponding first to seventh verify voltages VRF1 to VRF7. The first to seventh verify voltages VRF1 to VRF7 may be applied to the selected word line. It may be determined whether the threshold voltages of the selected memory cells are greater than the corresponding first to seventh verify voltages VRF1 to VRF7. The selected memory cells having threshold voltages greater than the corresponding first to seventh verify voltages VRF1 to VRF7 as a result of step S375 may become the program-inhibited cells.

Step S200 may end when the threshold voltages of all selected memory cells are determined as greater than the corresponding first to seventh verify voltages VRF1 to VRF7 at step S395. When the threshold voltages of at least some of the selected memory cells are determined as lower than the corresponding first to seventh verify voltages VRF1 to VRF7 at step S395, the process may proceed to step S315 and a subsequent program loop may be repeated.

As the fine program operation is performed as described above, the threshold voltage distribution corresponding to the erase state E_{IS} and the intermediate program state P_{IS} may be changed to the erase state E and the first to seventh target program states PV1 to PV7. The threshold voltages of the memory cells corresponding to the erase state E_{IS} may be changed to the erase state E and the first to seventh target program states PV1 to PV7. The threshold voltages of the memory cells corresponding to the intermediate program state P_{IS} may be changed to the fourth to seventh target program states PV4 to PV7.

The memory cells corresponding to the erase state E and the first to seventh target program states PV1 to PV7 may be divided according to the values of MSB, CSB and LSB. For example, the memory cell having the threshold voltage corresponding to the erase state E may have the MSB of 1, the CSB of 1, and the LSB of 1. For example, the memory cell having the threshold voltage corresponding to the first target program state PV1 may have the MSB of 0, the CSB of 0, and the LSB of 1.

For example, after completion of the partial-foggy-fine program operation, the LSB of each of the selected memory cells may be read through a fourth read voltage R4. All memory cells having lower threshold voltages than the fourth read voltage R4 may have the LSB of 1 and all memory cells having higher threshold voltages than the fourth read voltage R4 may have the LSB of 0. Therefore, an LSB read operation may be performed on the memory cells through the fourth read voltage R4. The read voltage for the LSB read operation after the partial-foggy program operation may be an intermediate read voltage R_{IS} and the read voltage for the LSB read operation after the fine program operation may be the fourth read voltage R4 greater than the intermediate read voltage R_{IS}.

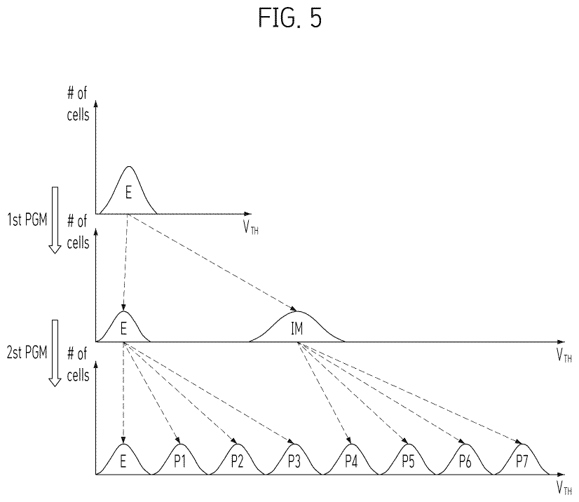

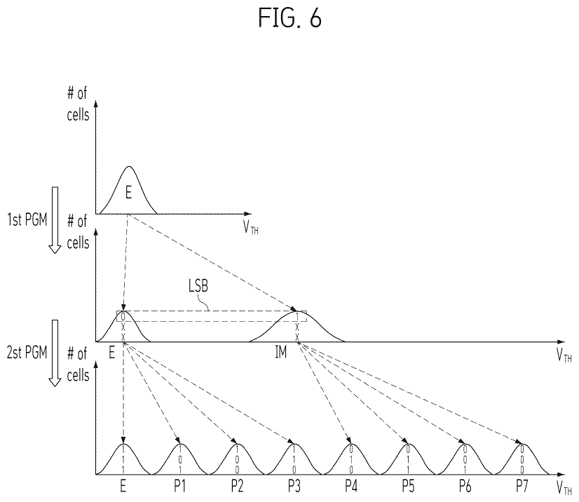

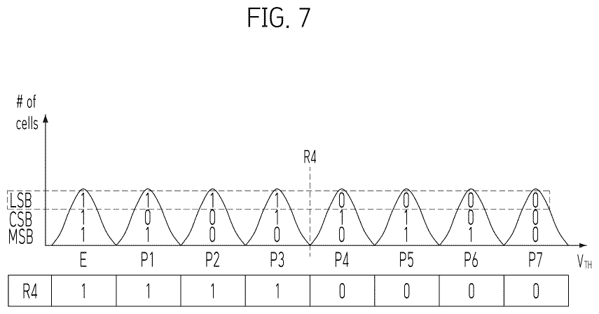

FIGS. 5 and 6 illustrate the partial-foggy-fine program scheme on TLCs. FIGS. 7 to 9 illustrate read operations on LSB, CSB and MSB pages of TLCs.

FIG. 7 illustrates an operation of reading the LSB page data.

In the case of the partial-foggy-fine program scheme of FIGS. 5 and 6, the partial-foggy program operation 1st PGM may be performed with only the LSB page data. The LSB page data of “0” and “1” may be distinguished according to a single read voltage.

Referring to FIGS. 5 and 6, the LSB page data of the memory cells having the threshold voltages corresponding to the erase state E and the first to third program states P1 to P3 may be “1” and the LSB page data of the memory cells having the threshold voltages corresponding to the fourth to seventh program state P4 to P7 may be “0”.

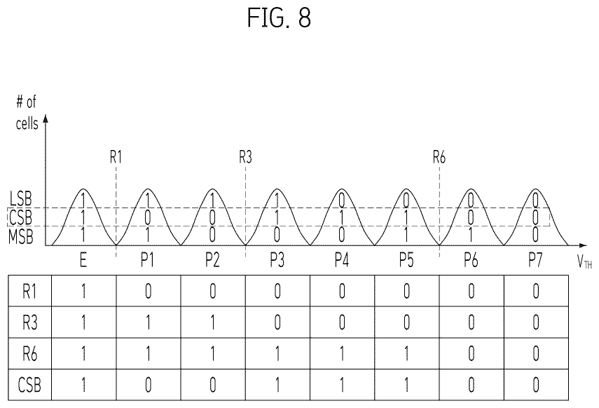

FIG. 8 illustrates an operation of reading the CSB page data.

The CSB page data may be obtained through three different read voltages. For example, the CSB page data may be obtained through the first, third and sixth read voltages R1, R3 and R6. The CSB data of the memory cell determined as the on-cell by the first read voltage R1 may be “1”. The CSB data of the memory cells determined as the off-cell by the read voltage R1 and determined as the on-cell by the third read voltage R3 may be “0”. The CSB data of the memory cells determined as the off-cell by the third read voltage R3 and determined as the on-cell by the sixth read voltage R6 may be “1”. The CSB data of the memory cells determined as the off-cell by the sixth read voltage R6 may be “0”.

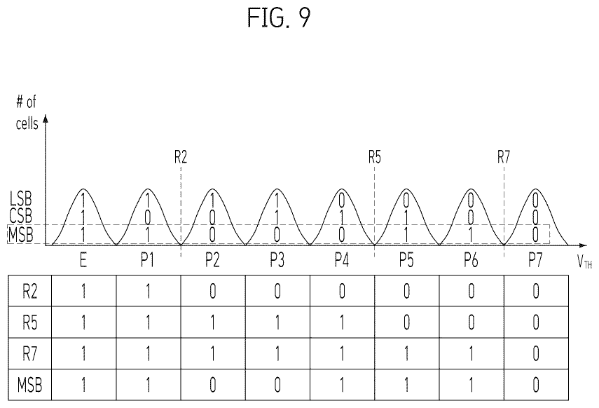

FIG. 9 illustrates an operation of reading the MSB page data.

The MSB page data may be obtained through three different read voltages. For example, the MSB page data may be obtained through the second, fifth and seventh read voltages R2, R5 and R7. The MSB data of the memory cell determined as the on-cell by the second read voltage R2 may be “1”. The MSB data of the memory cells determined as the off-cell by the second read voltage R2 and determined as the on-cell by the fifth read voltage R5 may be “0”. The MSB data of the memory cell determined as the off-cell by the fifth read voltage R5 and determined as the on-cell by the seventh read voltage R7 may be “1”. The CSB data of the memory cells determined as the off-cell by the seventh read voltage R7 may be “0”.

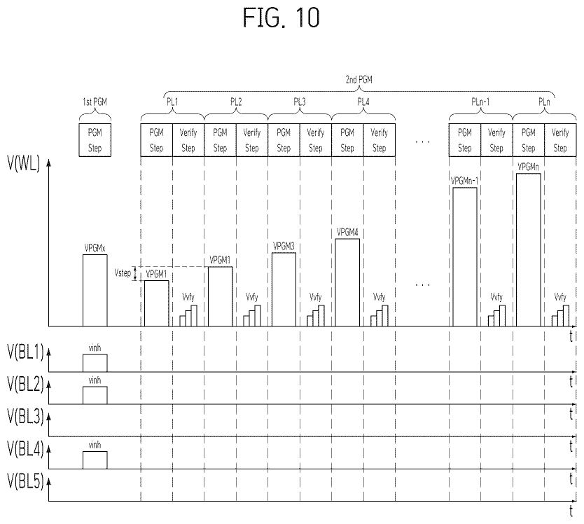

FIG. 10 illustrates voltages applied to a word line and bit lines during a foggy-fine program scheme on TLCs.

Referring to FIG. 10, the partial-foggy program operation 1st PGM may be an operation of programming the memory cells to have the threshold voltages corresponding to any one of the erase state and the intermediate state according to the data to be stored in each memory cells, the memory cells being connected to the selected word line. The magnitude of the threshold voltage corresponding to the intermediate state may be larger than the magnitude of the threshold voltage corresponding to the erase state. The memory cells programmed to have the threshold voltages corresponding to the intermediate state in the partial-foggy program operation 1st PGM may become to have the threshold voltages corresponding to any one of the fourth to seventh program states during the fine program operation 2nd PGM. The memory cells programmed to have the threshold voltages corresponding to the erase state in the partial-foggy program operation 1st PGM may become to have the threshold voltages corresponding to any one of the erase state and the first to third program states during the fine program operation 2nd PGM.

Referring to FIG. 10, it is assumed that target threshold voltages of the memory cells connected to the first, second and fourth bit lines BL1, BL2 and BL4 correspond to the third program state P3.

During the partial-foggy program operation 1st PGM, a fixed program voltage VPGMx having a predetermined voltage level may be applied to the selected word line. Although FIG. 10 shows a case where the fixed program voltage VPGMx is applied once during the partial-foggy program operation 1st PGM, the fixed program voltage VPGMx may be provided to the memory cells twice or more. The partial-foggy program operation 1st PGM may include a plurality of program loops. In this case, even though the program loops included in the partial-foggy program operation 1st PGM proceed, the level of the program voltage applied to the word line does not increase and the program voltage may be the fixed program voltage having the fixed voltage level.

When the fixed program voltage VPGMx is applied to the word line, a program inhibition voltage Vinh may be applied to the bit lines BL1, BL2 and BL4 to which the memory cells having the erase state and the first to third program states as the target program states are connected. When the fixed program voltage VPGMx is applied to the word line, a program permission voltage may be applied to the bit lines BL3 and BL5 to which the memory cells having any one of the fourth to seventh program states as the target program state are connected.

The partial-foggy program operation 1st PGM may be performed through one application of the fixed program voltage VPGMx, performance of the verify step and application of an additional program voltage. The number of times the program voltage is applied and whether the verify step is performed during the partial-foggy program operation 1st PGM are not limited.

The fine program operation 2nd PGM may include a plurality of program loops PL1 to PLn. One program loop includes a program voltage apply step PGM Step of applying a program voltage to a selected word line and a verify step of sensing whether a threshold voltage of each memory cell reaches a threshold voltage corresponding to a target program state. Each time the program loop proceeds, a level of the program voltage applied to the word line may increase by a step voltage Vstep compared to a program voltage in a previous program loop. Here, the step voltage may be a preset voltage value. This is called an incremental step pulse program (ISPP) scheme. Even though program loops corresponding to a preset maximum number of loops are performed, when all memory cells connected to the selected word line do not reach the target program state, it may be determined that the program operation is failed. The number of program states verified in each program loop may be at least two or more program states.

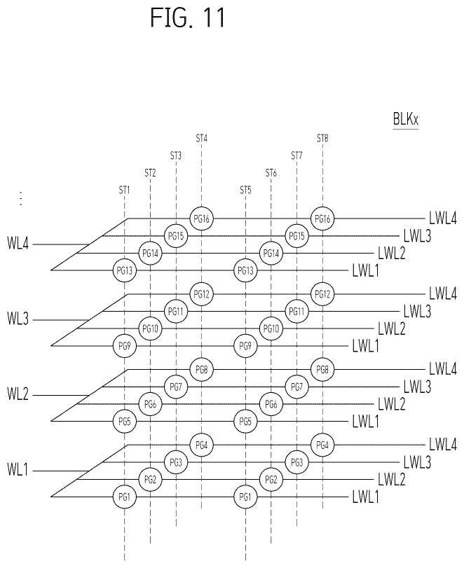

FIG. 11 schematically illustrates pages included in a memory block.

Referring to FIG. 11, the memory block BLKx may be connected to a plurality of physical word lines. One physical word line may be commonly connected to four logical word lines. Memory cells connected to any one of the logical word lines may configure one page. For example, each of first to fourth physical word lines WL1 to WL4 may be commonly connected to first to fourth logical word lines LWL1 to LWL4.

For example, first to fourth strings ST1 to ST4 may be commonly connected to a bit line and fifth to eighth strings ST5 to ST8 may be commonly connected to another bit line.

For example, the number of logical word lines connected to one physical word line may be determined according to the number of strings commonly connected to one bit line. For example, when five strings are commonly connected to one bit line, one physical word line may be commonly connected to five local word lines. In this case, one physical word line may include five pages. Among the five pages, a programmed string and a not-yet-programmed string may be determined according to a string select signal (e.g., signals applied to the drain select line or the source select line).

The first logical word line LWL1 may be selected by the first string ST1 and the fifth string ST5. The second logical word line LWL2 may be selected by the second string ST2 and the sixth string ST6. The third logical word line LWL3 may be selected by the third string ST3 and the seventh string ST7. The fourth logical word line LWL4 may be selected by the fourth string ST4 and the eighth string ST8. One page may be selected by one logical word line and one physical word line.

That is, the first physical word line WL1 may include first to fourth pages PG1 to PG4. The second physical word line WL2 may include fifth to eighth pages PG5 to PG8. The third physical word line WL3 may include ninth to twelfth pages PG9 to PG12. The fourth physical word line WL4 may include thirteenth to sixteenth pages PG13 to PG16.

As discussed above, a partial-foggy program operation may be the foggy program operation forming the threshold voltage distribution corresponding to a part of all states supposed to be formed. A partial-foggy-fine program scheme may include the partial-foggy program operation and a fine program operation. In this disclosure, an all-foggy program operation may be a foggy program operation, which forms the threshold voltage distribution corresponding to all states supposed to be formed. In this disclosure, an all-foggy-fine program scheme may include the all-foggy program operation and a fine program operation. The all-foggy-fine program scheme may be known as the one-shot program scheme.

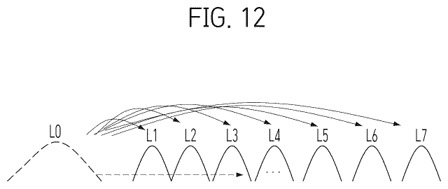

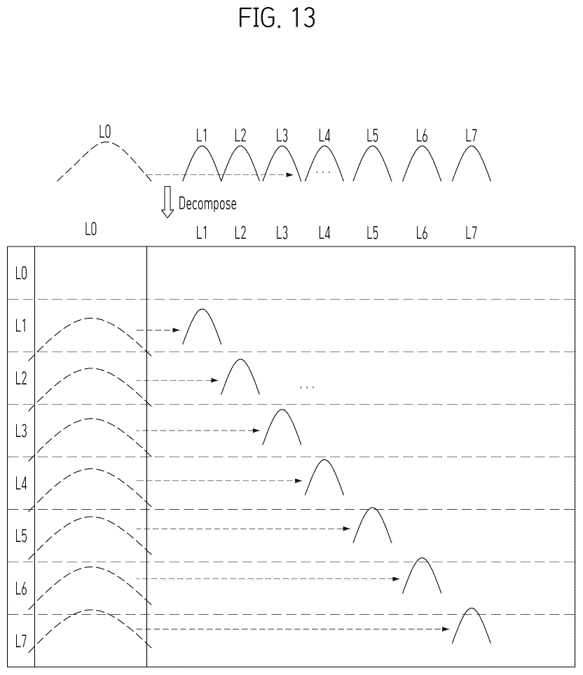

FIGS. 12 and 13 schematically illustrate a one-shot program scheme on TLCs.

Referring to FIGS. 12 and 13, the TLC may be programmed to assume one of the program states L1 to L7 from the erase state L0. Each program state may be verified sequentially until the verification of the state passes or a number of the applied programming pulse reaches a maximum number, and the program operations may end.

For example, at the first programming loop, the memory cells to be programmed to the target program state L1 are verified. After the fifth programming loop, the verification operations performed on the memory cells of the target program state L1 may end. After the fifth programming loop, where the verification pulse is applied on the memory cells of the target program state L1, the verification of the target program state L1 passes and the TLC of the program state L1 may no longer be programmed. Similar techniques may be applied to the TLC to be programmed to the program states L2 to L7.

Through the multiple programming loops, the memory cells may be programmed from the erase state L0 to the respective program states L1 to L7. At each programming loop of the one-shot program approach, programming pulses may be required to be simultaneously applied to all unverified memory cells. When the verification passes for a memory cell of the target program state, a programming inhibition pulse may be applied to the verification-passed memory cell. For example, at the first programming loop, a first programming pulse may be applied to the memory cells to be programmed to the program states L1 to L7 simultaneously. After the fifth programming loop, the verification of the target program state L1 may pass. At the sixth programming loop, a sixth programming pulse may be applied to the memory cells to be programmed to the respective program states L2 to L7 and the memory cells of the program state L1 may be program-inhibited.

Although not illustrated, during the one-shot program scheme, all-foggy program operation and fine program operation may be performed on memory cells.

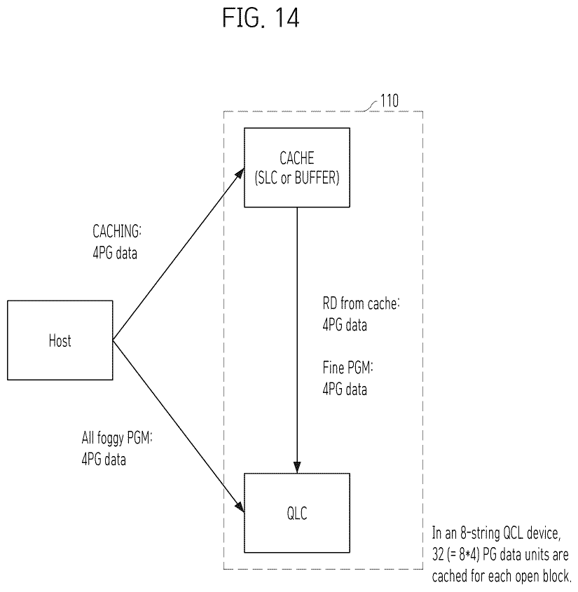

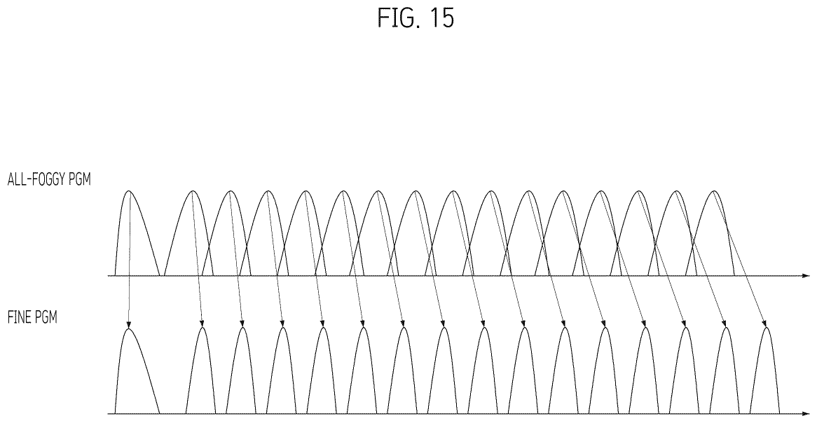

FIGS. 14 and 15 schematically illustrate a one-shot program scheme on QLCs.

The QLC may store therein the least significant bit (LSB), lower-central significant bit (LCSB), upper-central significant bit (UCSB) and most significant bit (MSB), respectively. The LSBs stored in the QLCs of a LSB row among the QLCs connected to a word line may form the LSB page. In a similar manner, the MSBs may form the MSB page, the UCSBs may form the UCSB page and the LCSBs may form the LCSB page between the UCSB and LSB pages. The QLCs may store 4-page data of LSB, LCSB, UCSB and MSB.

According to the one-shot program scheme shown in FIGS. 14 and 15, the 4-page data (e.g., the LSB, LCSB, UCSB and MSB page data) needs to be programmed to the QLC twice at different points in time. According to the one-shot program scheme, the all-foggy program operation is performed at the first point of time when the host provides the memory system with the 4-page data (“ALL foggy PGM: 4PG data” in FIG. 14). At the first point of time, the memory system needs to cache the same 4-page data (“CACHING: 4PG data” in FIG. 14) for the subsequent fine program operation to be performed at the second point of time (“RD from CACHE: 4PG data” and “Fine PGM: 4PG data” in FIG. 14) because the result of the all-foggy program operation on the QLC is not readable. Here, the cache illustrated in FIG. 14 may be either a SLC or a volatile memory. In an example of an 8-string QCL device, 32-page data (=8 strings * 4 pages) are cached for each open block.

According to the partial-foggy-fine program scheme, which is different from the one-shot program scheme, 2-page data (e.g., the LSB and LCSB page data) is programmed directly from the host 102 to the QLCs without caching any data during the partial-foggy program operation. Unlike the one-shot program scheme, the 2-page data is readable as the result of the partial-foggy program operation. Thereafter, the memory system internally reads the stored 2-page data, i.e., the result of the partial-foggy program operation, combines the read 2-page data with the other 2-page data (e.g., the UCSB and MSB page data), which is provided from the host, and performs the fine program operation on the QLC with the combined 4-page data.

As the NAND memory technology scales to higher BPC, the reliability aspect degrades even further. While conventional sequential multi-step program approach is acceptable for the reliability of 3 BPC, i.e., TLC, required is a more complex approach for the reliability of 4 BPC, i.e., QLC.

In general, the partial-foggy-fine program scheme or the one-shot program scheme is applied to the QLCs to achieve the best possible cell distribution.

In an embodiment, a hybrid-foggy-fine program scheme may be applied to the QLCs, which will be described below. According to the hybrid-foggy-fine program scheme, a sequence of hybrid-foggy program operation and hybrid-fine program operation may be performed on QLCs. According to the hybrid-foggy-fine program scheme, the system cache requirement may be reduced for the QLCs while maintaining the reliability margin of the QLCs.

The hybrid-foggy program operation may be performed on a first page-group of QLCs to program the first page-group of QLCs to become to have significant bit values in a foggy state or a non-readable state. In this disclosure, the first page-group of QLCs may be supposed to have higher significant bit values (e.g., the UCSB and MSB values) when a program operation is completed. The hybrid-foggy program operation may be performed on a second page-group of QLCs to program the second page-group of QLCs to become to have significant bit values in a fine state or a readable state. In this disclosure, the second page-group of QLCs may be supposed to have lower significant bit values (e.g., the LSB and LCSB values) when a program operation is completed.

For example, the first page-group of QLCs may be supposed to have the higher significant bit values of most significant bit (MSB) and upper central significant bit (UCSB) upon completion of a program operation. For example, the second page-group of QLCs may be supposed to have the lower significant bit values of least significant bit (LSB) and lower central significant bit (LCSB) upon completion of a program operation. For example, the first page-group of QLCs may be 2-page QLCs of MSB and UCSB. For example, the second page-group of QLCs may be 2-page QLCs of LSB and LCSB.

When the data stored in the first page-group of QLCs becomes in a non-readable state, the data cannot be read from the first page-group of QLCs according to any read voltage level due to no read margins during the hybrid-fine program operation. When the data stored in the second page-group of QLCs becomes in a readable state, the data may be read from the second page-group of QLCs according to an appropriate read voltage level because of enough read margins during the hybrid-fine program operation.

The hybrid-fine program operation may program 4-page data (e.g., the LSB, LCSB, UCSB and MSB page data) into the first and second page-groups of QLCs to form the threshold voltage distributions with enough read margins.

The hybrid-foggy-fine program scheme may mitigate the majority of the cell margin loss factor, which is caused by the movement of higher voltage levels between the hybrid-foggy program operation and the hybrid-fine program operation, while improving the system cache burden because of the readable state of the second page-group of QLCs upon completion of the hybrid-foggy program operation.

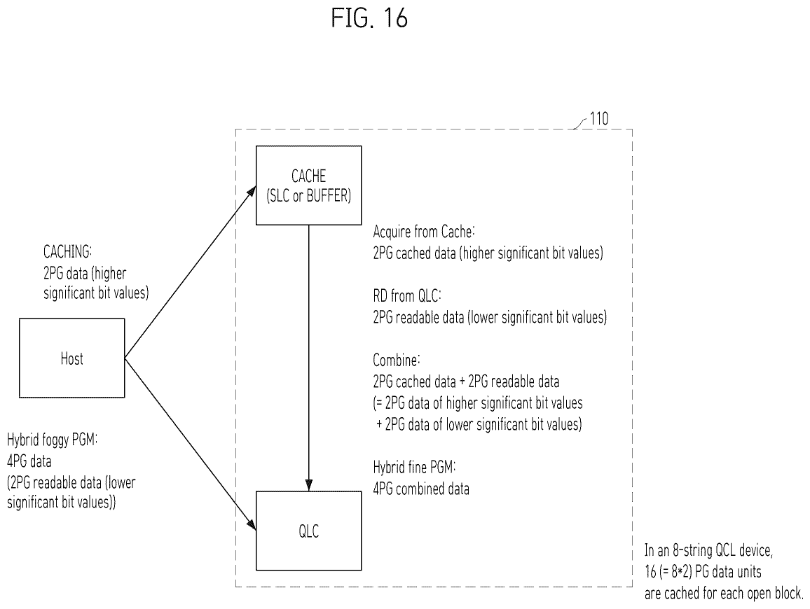

FIG. 16 schematically illustrates the hybrid-foggy-fine program scheme on QLCs.

According to the hybrid-foggy-fine program scheme, the hybrid-foggy program operation may be performed on the first and second page-groups of QLCs (“Hybrid foggy PGM: 4PG data (2PG readable data (lower significant bit values))” in FIG. 16) with the 4-page data (e.g., the LSB, LCSB, UCSB and MSB page data). The 4-page data for the first and second page-groups of QLCs may be provided from the host 102. The first page-group of QLCs (e.g., the MSB page and UCSB page) may be supposed to have higher significant bit values (e.g., the MSB value and UCSB value) when a program operation is completed. The second page-group of QLCs (e.g., the LSB page and LCSB page) may be supposed to have lower significant bit values (e.g., the LSB value and LCSB value) when a program operation is completed. The hybrid-foggy program operation may be performed on the first page-group of QLCs to program the first page-group of QLCs to become to have the significant bit values (e.g., the UCSB and MSB values) in a foggy state or a non-readable state. The hybrid-foggy program operation may be performed on the second page-group of QLCs to program the second page-group of QLCs to become to have the significant bit values (e.g., the LSB and LCSB values) in a fine state or a readable state. When the data stored in the first page-group of QLCs becomes in the non-readable state, the data cannot be read from the first page-group of QLCs according to any read voltage level due to no read margins during the hybrid-fine program operation. When the data stored in the second page-group of QLCs becomes in the readable state, the data may be read from the second page-group of QLCs according to an appropriate read voltage level because of enough read margins during the hybrid-fine program operation.

While the hybrid-foggy program operation is performed on the first and second page-groups of QLCs, the 2-page data (e.g., the MSB page data and UCSB page data) for the first page-group of QLCs may be cached (“CACHING: 2PG data (higher significant bit values)” in FIG. 16) into the cache. The cache illustrated in FIG. 16 may be either a SLC or a volatile memory.

During the hybrid-fine program operation after completion of the hybrid-foggy program operation, the memory device 150 may internally read the readable 2-page data (e.g., the LSB page data and LCSB page data in the readable state) from the second page-group of QLCs (“RD from QLC: 2PG readable data (lower significant bit values)” in FIG. 16) and acquire the non-readable 2-page data (e.g., the MSB page data and UCSB page data) from the cache (“Acquire from Cache: 2PG cached data (higher significant bit values)” in FIG. 16). As discussed above, the data stored in the first page-group of QLCs (e.g., the MSB page and UCSB page) may become in the non-readable state through the hybrid-foggy program operation and the non-readable 2-page data cannot be read from the first page-group of QLCs during the subsequent hybrid-fine program operation. Instead, the non-readable 2-page data may be acquired from the cache during the hybrid-fine program operation.

During the hybrid-fine program operation, the memory system 110 may combine the 2-page data (e.g., the LSB page data and LCSB page data) read from the second page-group of QLCs with the 2-page data (e.g., the MSB page data and UCSB page data) acquired from the cache to generate combined 4-page data (e.g., the LSB page data, LCSB page data, UCSB page data and MSB page data) (“Combine: 2PG cached data+2PG readable data (=2PG data of higher significant bit values+2PG data of lower significant bit values)” in FIG. 16).

The memory system 110 may perform, with the combined 4-page data, the hybrid-fine program operation on the first and second page-groups of QLCs (“Hybrid fine PGM: 4PG combined data” in FIG. 16).

According to the hybrid-foggy-fine program scheme in an example of an 8-string QCL device, 16-page data (=8 strings * 2 pages) are cached for each open block. When compared with the one-shot program scheme shown in FIGS. 14 and 15, the hybrid-foggy-fine program scheme may reduce the cache requirement by 50% over the one-shot program scheme.

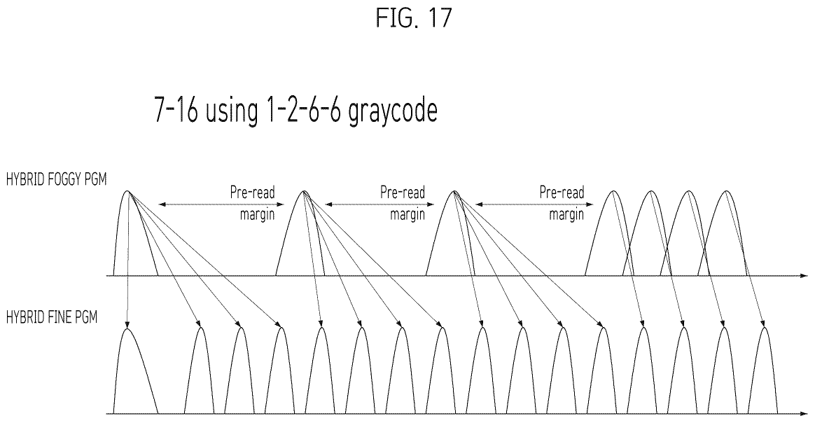

FIGS. 17 to 21 schematically illustrate various embodiments of the hybrid-foggy-fine program scheme on QLCs.

The hybrid-foggy program operation may be performed on the first and second page-groups of QLCs with the 4-page data. The hybrid-foggy program operation may be performed on the first page-group of QLCs to program the first page-group of QLCs to become to have the significant bit values (e.g., the UCSB and MSB values) in a foggy state or a non-readable state. The hybrid-foggy program operation may be performed on the second page-group of QLCs to program the second page-group of QLCs to become to have the significant bit values (e.g., the LSB and LCSB values) in a fine state or a readable state.

In FIG. 17, “7-16” means the 7 number of cell-states as the result of the hybrid-foggy program operation and the 16 number of cell-states as the result of the hybrid-fine program operation.

As a result of the hybrid-foggy program operation according to the embodiment illustrated in FIG. 17, formed may be the threshold voltage distribution corresponding to 7 states with 3 valleys each having a high margin for the internal read of the readable 2-page data (e.g., the LSB page data and LCSB page data in the readable state) from the second page-group of QLCs.

In FIG. 17, “1-2-6-6 graycode” means an exemplary QLC graycode scheme with the numbers of read levels for respective LSB, LCSB, UCSB and MSB pages. The read level usually occurs at a transition of bit value from “0” to “1” or “1” to “0”. In the example of the “1-2-6-6 graycode” scheme, a single read level may be required for reading data from the LSB page, 2 number of read levels may be required for reading data from the LCSB page, 6 number of read levels may be required for reading data from the UCSB page and 6 number of read levels may be required for reading data from the MSB page.

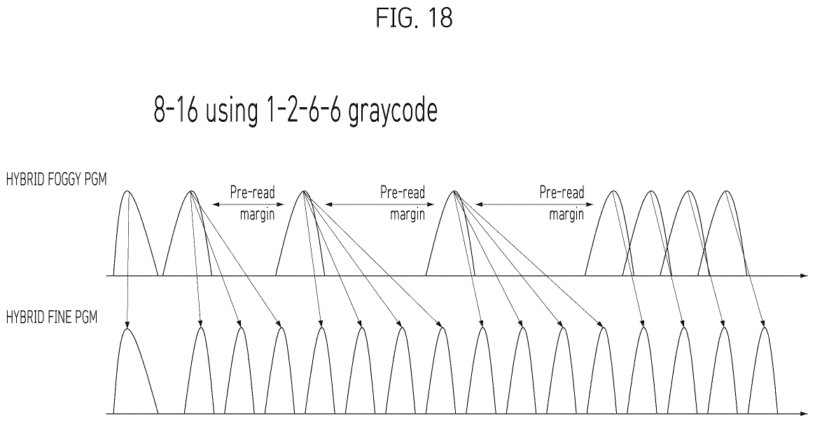

In FIG. 18, “8-16” means the 8 number of cell-states as the result of the hybrid-foggy program operation and the 16 number of cell-states as the result of the hybrid-fine program operation.

As a result of the hybrid-foggy program operation according to the embodiment illustrated in FIG. 18, formed may be the threshold voltage distribution corresponding to 8 states with 3 valleys each having a high margin for the internal read of the readable 2-page data (e.g., the LSB page data and LCSB page data in the readable state) from the second page-group of QLCs.

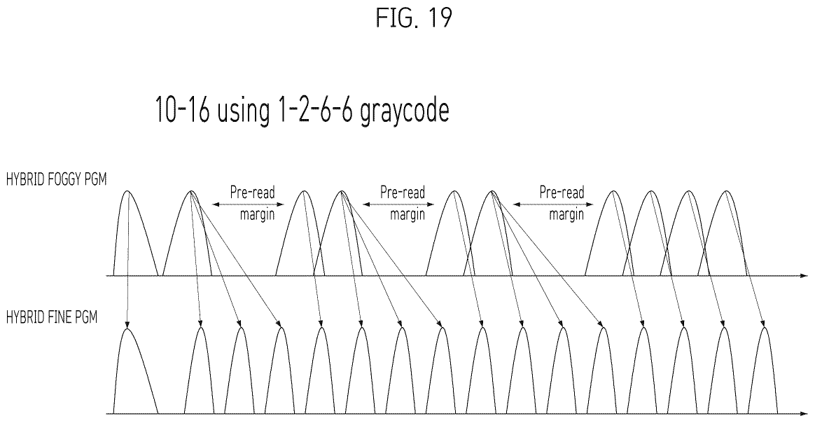

In FIG. 19, “10-16” means the 10 number of cell-states as the result of the hybrid-foggy program operation and the 16 number of cell-states as the result of the hybrid-fine program operation.

As a result of the hybrid-foggy program operation according to the embodiment illustrated in FIG. 19, formed may be the threshold voltage distribution corresponding to 10 states with 3 valleys each having a median margin for the internal read of the readable 2-page data (e.g., the LSB page data and LCSB page data in the readable state) from the second page-group of QLCs.

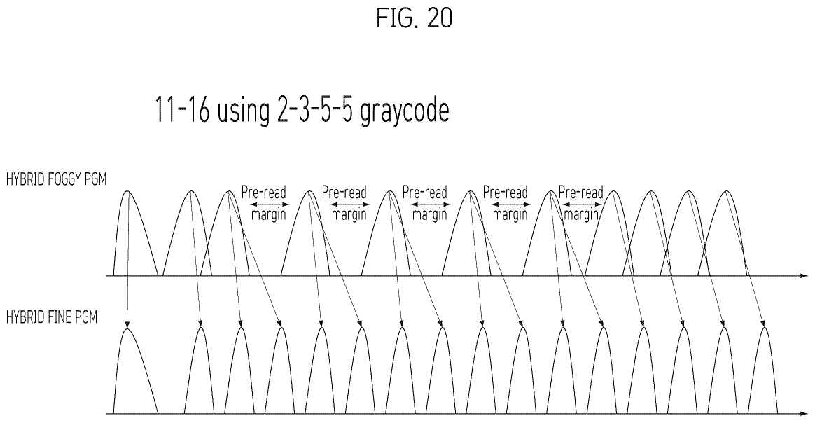

In FIG. 20, “11-16” means the 11 number of cell-states as the result of the hybrid-foggy program operation and the 16 number of cell-states as the result of the hybrid-fine program operation.

As a result of the hybrid-foggy program operation according to the embodiment illustrated in FIG. 20, formed may be the threshold voltage distribution corresponding to 11 states with 5 valleys each having a low margin for the internal read of the readable 2-page data (e.g., the LSB page data and LCSB page data in the readable state) from the second page-group of QLCs.

In FIG. 20, “2-3-5-5 graycode” means an exemplary QLC graycode scheme with the numbers of read levels for respective LSB, LCSB, UCSB and MSB pages. In the example of the “2-3-5-5 graycode” scheme, 2 number of read levels may be required for reading data from the LSB page, 3 number of read levels may be required for reading data from the LCSB page, 5 number of read levels may be required for reading data from the UCSB page and 5 number of read levels may be required for reading data from the MSB page.

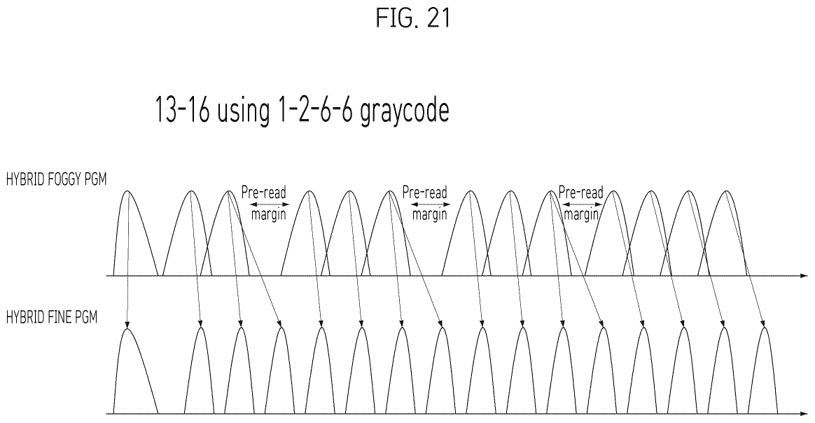

In FIG. 21, “13-16” means the 13 number of cell-states as the result of the hybrid-foggy program operation and the 16 number of cell-states as the result of the hybrid-fine program operation.

As a result of the hybrid-foggy program operation according to the embodiment illustrated in FIG. 21, formed may be the threshold voltage distribution corresponding to 13 states with 3 valleys each having a low margin for the internal read of the readable 2-page data (e.g., the LSB page data and LCSB page data in the readable state) from the second page-group of QLCs.

FIGS. 17 to 21 show respective cases of the read margins of the read levels for the LSB and LCSB pages. For example, in the example of the “1-2-6-6 graycode” scheme, 3 number of read margins of the read levels for the LSB and LCSB pages. For example, in the example of the “2-3-5-5 graycode” scheme, 5 number of read margins of the read levels for the LSB and LCSB pages.

The main trade off in the above-discussed embodiments may be the read margin after the hybrid-foggy program operation and the read margin after the hybrid-fine program operation. Typically, a narrower read margin after the hybrid-foggy program operation may result in the better read margin after the hybrid-fine program operation. However, during the hybrid-fine program operation, any bit-error caused by the internal reading of the readable data may propagate as misplacement error bits during the programming the combined data. Therefore, a healthy read margin needs to be formed after the hybrid-foggy program operation.

In terms of NAND reliability margin in the QLCs, the one-shot program scheme benefits the partial-foggy-fine program scheme in two physical mechanisms: Z-interference loss and quick charge loss (QCL).

The Z-interference is the coupling of QLCs on adjacent victim word lines during programming of a target word line. The current QLC program algorithm employs the foggy-fine program scheme to reduce this loss but cannot be fully mitigated.

The QCL loss is due to de-trapping of electrons in the oxide between storage nitride and pillar which happens in the short time frame after program verify and is proportional to the number of trapped electrons in the shallow tunnel oxide (higher trapped electron~higher QCL loss).

Both the loss mechanisms are a function of VT delta between the foggy and fine program operations. So, for optimal state-width/RWB (Read Window Budget: the sum of valley margins between adjacent distributions. Better/lower state-width translates to higher RWB margin), minimal cells movement due to the fine program operation is preferred [loss∝VT (fine program operation)−VT (foggy program operation)].

Thus, higher VT delta between the foggy and fine program operations would result in higher loss. The partial-foggy-fine program scheme has worse RWB than the one-shot program scheme because the delta of max VT between the foggy and fine program operations is higher when compared with the one-shot program scheme.

The hybrid-foggy-fine program scheme helps reduce this loss of the partial-foggy-fine program scheme by placing the QLCs, the data of which is supposed to have higher significant bit values, in the foggy state or the non-readable state while placing the QLCs, the data of which is supposed to have lower significant bit values, in the fine state or the readable state during the hybrid-foggy program operation. The placing of the QLCs in the foggy state or the non-readable state may help reduce margin loss. The placing of the QLCs in the fine state or the readable state may help reduce the system cache burden. The partial-foggy-fine program scheme shows significant loss when compared with the one-shot program scheme whereas the hybrid-foggy-fine program scheme helps improve this loss while also improving the cache burden for system.

Although the foregoing embodiments have been illustrated and described in some detail for purposes of clarity and understanding, the present invention is not limited to the embodiments provided. There are many alternative ways of implementing the invention, as one skilled in the art will appreciate in light of the foregoing disclosure. The disclosed embodiments are thus illustrative, not restrictive. The present invention is intended to embrace all modifications and alternatives of the disclosed embodiments. Furthermore, the disclosed embodiments may be combined to form additional embodiments.

Indeed, implementations of the subject matter and the functional operations described in the present disclosure may be implemented in various systems, digital electronic circuitry, or in computer software, firmware, or hardware, including the structures disclosed in this specification and their structural equivalents, or in combinations of one or more of them. Embodiments of the subject matter described in this specification may be implemented as one or more computer program products, i.e., one or more modules of computer program instructions encoded on a tangible and non-transitory computer readable medium for execution by, or to control the operation of, data processing apparatus. The computer readable medium may be a machine-readable memory device, a machine-readable storage substrate, a memory device, a composition of matter affecting a machine-readable propagated signal, or a combination of one or more of them. The term “data processing unit” or “data processing apparatus” encompasses all apparatus, devices, and machines for processing data, including by way of example a programmable processor, a computer, or multiple processors or computers. The apparatus may include, in addition to hardware, code that creates an execution environment for the computer program in question, e.g., code that constitutes processor firmware, a protocol stack, a database management system, an operating system, or a combination of one or more of them.

A computer program (also known as a program, software, software application, script, or code) may be written in any form of programming language, including compiled or interpreted languages, and it may be deployed in any form, including as a stand-alone program or as a module, component, subroutine, or other unit suitable for use in a computing environment. A computer program does not necessarily correspond to a file in a file system. A program may be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program may be deployed to be executed on one computer or on multiple computers that are located at one site or distributed across multiple sites and interconnected by a communication network.

The processes and logic flows described in this specification may be performed by one or more programmable processors executing one or more computer programs to perform functions by operating on input data and generating output. The processes and logic flows may also be performed by, and apparatus may also be implemented as, special purpose logic circuitry, e.g., an FPGA (field programmable gate array) or an ASIC (application specific integrated circuit).

Processors suitable for the execution of a computer program include, by way of example, both general and special purpose microprocessors, and one or more processors of any type of digital computer. Generally, a processor will receive instructions and data from a read only memory or a random-access memory or both. The essential elements of a computer are a processor for performing instructions and one or more memory devices for storing instructions and data. Generally, a computer will also include, or be operatively coupled to receive data from or transfer data to, or both, one or more mass memory devices for storing data, e.g., magnetic, magneto optical disks, or optical disks. However, a computer need not have such devices. Computer readable media suitable for storing computer program instructions and data include all forms of nonvolatile memory, media and memory devices, including by way of example semiconductor memory devices, e.g., EPROM, EEPROM, and flash memory devices. The processor and the memory may be supplemented by, or incorporated in, special purpose logic circuitry.

While the present disclosure contains many specifics, these should not be construed as limitations on the scope of any invention or of what may be claimed, but rather as descriptions of features that may be specific to particular embodiments of particular inventions. Certain features that are described in the present disclosure in the context of separate embodiments may also be implemented in combination in a single embodiment. Conversely, various features that are described in the context of a single embodiment may also be implemented in multiple embodiments separately or in any suitable sub-combination. Moreover, although features may be described above as acting in certain combinations, one or more features from a combination may in some cases be excised from the combination, and the combination may be directed to a sub-combination or a variation of a sub-combination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in the present disclosure should not be understood as requiring such separation in all embodiments.

Only a few embodiments and examples are described and other embodiments, enhancements and variations may be made based on what is described and illustrated in the present disclosure. Furthermore, the embodiments may be combined to form additional embodiments.

What is claimed is:

1. A memory system comprising:
a memory device including a group of nonvolatile memory cells each configured to store therein multiple bits, which comprises higher and lower significant bits, the group comprising first and second parts;
a cache; and
a control circuit configured to:
cache the higher significant bits into the cache, and
control the memory device to perform a sequence of foggy and fine program operations on the group, wherein:
the foggy program operation is an operation of programming the first part with the higher significant bits to become in a non-readable state and programming the second part with the lower significant bits to become in a readable state, and
the fine program operation is an operation of programming the group with the multiple bits, which are combination of the higher significant bits from the cache and the lower significant bits from the second part.

2. The memory system of claim 1, wherein the cache includes one or more nonvolatile single level cells (SLCs).

3. The memory system of claim 1, wherein the multiple bits are four bits.

4. The memory system of claim 3, wherein the fine program operation is the operation of programming the group with the multiple bits to have threshold voltages corresponding to sixteen erase and program states.

5. The memory system of claim 3, wherein
the higher significant bits are two bits of most significant bit (MSB) and upper-central significant bit (UCSB), and
the lower significant bits are two bits of least significant bit (LSB) and lower-central significant bit (LCSB).

6. The memory system of claim 5, wherein:
the first part includes the memory cells for MSB and UCSB pages, and
the second part includes the memory cells for LSB and LCSB pages.

7. The memory system of claim 4, wherein the foggy program operation is the operation of programming to have threshold voltages corresponding to 7 states with 3 valleys each having a high margin for internal read of 2 pages of data.

8. The memory system of claim 4, wherein the foggy program operation is the operation of programming to have threshold voltages corresponding to 8 states with 3 valleys each having a high margin for internal read of 2 pages of data.

9. The memory system of claim 4, wherein the foggy program operation is the operation of programming to have threshold voltages corresponding to 10 states with 3 valleys each having a median margin for internal read of 2 pages of data.

10. The memory system of claim 4, wherein the foggy program operation is the operation of programming to have threshold voltages corresponding to 11 states with 5 valleys each having a low margin for internal read of 2 pages of data.

11. The memory system of claim 4, wherein the foggy program operation is the operation of programming to have threshold voltages corresponding to 13 states with 3 valleys each having a low margin for internal read of 2 pages of data.

12. An operating method of a memory system, the operating method comprising:
caching higher significant bits into a cache; and
performing, with multiple bits comprising the higher and lower significant bits, a sequence of foggy and fine program operations on a group of nonvolatile memory cells comprising first and second parts, wherein:
the foggy program operation is an operation of programming the first part with the higher significant bits to become in a non-readable state and programming the second part with the lower significant bits to become in a readable state, and
the fine program operation is an operation of programming the group with the multiple bits, which are combination of the higher significant bits from the cache and the lower significant bits from the second part.

13. The operating method of claim 12, wherein the multiple bits are four bits.

14. The operating method of claim 13, wherein the fine program operation is the operation of programming the group with the multiple bits to have threshold voltages corresponding to sixteen erase and program states.

15. The operating method of claim 13, wherein
the higher significant bits are two bits of most significant bit (MSB) and upper-central significant bit (UCSB), and
the lower significant bits are two bits of least significant bit (LSB) and lower-central significant bit (LCSB).

16. The operating method of claim 14, wherein the foggy program operation is the operation of programming to have threshold voltages corresponding to 7 states with 3 valleys each having a high margin for internal read of 2 pages of data.

17. The operating method of claim 14, wherein the foggy program operation is the operation of programming to have threshold voltages corresponding to 8 states with 3 valleys each having a high margin for internal read of 2 pages of data.

18. The operating method of claim 14, wherein the foggy program operation is the operation of programming to have threshold voltages corresponding to 10 states with 3 valleys each having a median margin for internal read of 2 pages of data.

19. The operating method of claim 14, wherein the foggy program operation is the operation of programming to have threshold voltages corresponding to 11 states with 5 valleys each having a low margin for internal read of 2 pages of data.

20. The operating method of claim 14, wherein the foggy program operation is the operation of programming to have threshold voltages corresponding to 13 states with 3 valleys each having a low margin for internal read of 2 pages of data.
